(19) United States
(12) Patent Application Publication
(10) Pub. No.: US 2026/0052642 A1
(43) Pub. Date: Feb. 19, 2026

(54) COMPUTING SYSTEM ARCHITECTURE

(71) Applicant: Apple Inc., Cupertino, CA (US)

(72) Inventors: Abidur R. CHOWDHURY, San Francisco, CA (US); Anthony J. AIELLO, Santa Cruz, CA (US); Arash NAGHIB LAHOUTI, San Jose, CA (US); Chi XU, Santa Clara, CA (US); David H. NARAJOWSKI, San Jose, CA (US); David P. TARKINGTON, Sunnyvale, CA (US); Eric R. PRATHER, Portola Valley, CA (US); Kainoa KWON-PEREZ, San Francisco, CA (US); Kwonil D. FLEISCHMAN, San Jose, CA (US); Ricardo FORT, Cupertino, CA (US)

(21) Appl. No.: 18/807,745

(22) Filed: Aug. 16, 2024

(51) Int. Cl. H05K 7/20

(52) U.S. Cl. CPC H05K 7/20172; H05K 7/20409

(57) ABSTRACT

An electronic device includes several thermal components designed to fit within a housing defined by housing components. The thermal components may include a thermal slug, a heat pipe, and a fin stack. The fin stack may include radial fans that allow the fin stack to align with a blower, including a fan outlet of the blower. The heat pipe may bend and curve around the blower. Additionally, the electronic device may include a power system and a circuit board stacked over the blower. Several pins may be used to align the power system and the circuit board within the housing of the electronic device.

### TECHNICAL FIELD

This application is directed to electronic devices, and more particularly, to internal layouts of electronic devices.

### BACKGROUND

Electronic devices include computing systems for processing various operations. Additionally, electronic devices include a thermal system to cool one or more components of the computing system.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates a perspective view of an embodiment of an electronic device, in accordance with aspects of the present disclosure.

FIG. 2 illustrates an exploded view of an embodiment of an electronic device, in accordance with aspects of the present disclosure.

FIG. 3 illustrates a perspective view of a power system of an electronic device, in accordance with aspects of the present disclosure.

FIG. 4 and FIG. 5 illustrate perspective views of a computing system an electronic device, in accordance with aspects of the present disclosure.

FIG. 6 and FIG. 7 illustrate perspective views of a thermal system of an electronic device, in accordance with aspects of the present disclosure.

FIG. 8 and FIG. 9 illustrate perspective views of a blower of an electronic device, in accordance with aspects of the present disclosure.

FIG. 10 illustrates a perspective view of an embodiment of a computing system and thermal components of an electronic device, in accordance with aspects of the present disclosure.

FIG. 11 illustrates an internal perspective view of an embodiment of a housing component of an electronic device, in accordance with aspects of the present disclosure.

FIG. 12 illustrates a perspective view of an embodiment of a wireless communication system of an electronic device, in accordance with aspects of the present disclosure.

FIG. 13 illustrates a bottom view of an embodiment of an electronic device, showing features of a housing component, in accordance with aspects of the present disclosure.

FIG. 14A and FIG. 14B illustrate partial cross sectional views of an embodiment of an electronic device, in accordance with aspects of the present disclosure.

FIG. 15 illustrates a perspective view of several components of an electronic device, further showing an exemplary airflow path through the components, in accordance with aspects of the present disclosure.

FIG. 16 illustrates a perspective view of an alternate embodiment of a thermal component, in accordance with aspects of the present disclosure.

FIG. 17 illustrates an electronic system with which one or more implementations of the subject technology may be implemented.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

The present disclosure is directed to electronic devices, and in particular, to the internal layout and architecture of components within electronic devices. There is a gradual trend for the overall footprint of electronic devices to reduce over time. While this trend offers a smaller form factor, other issues may subsequently arise. For example, thermal management of components (e.g., integrated circuits) becomes more challenging with less space within an electronic device, particularly when these components become more complex and capable of generating additional heat (e.g., thermal energy) during operation. In this regard, other components, such as heat pipes and blowers, may include design changes to fit within the relatively small space of electronic devices shown and described herein.

Additionally, the blower base, or pillow, may be angled to receive components such as a mount that carries thermal components, such as a fin stack and a heat pipe. Additionally, the base may further include a curved surface. Moreover, the fin stack may include fins that extend radially outward, thus confirming to the curvature of the blower base. Also, the blower may include a housing that is chamfered, or angled, in order to provide space for thermal components, such as a heat pipe.

In order to manage radio frequency (RF) features, wireless communication components (e.g., antennas and circuitry for protocol including WIFI® and BLUETOOTH®) may be separated from other components (e.g., logic board, power supply unit) by a cage (e.g., Faraday cage. In this regard, the wireless communication components are shieled from noise, such as electromagnetic interference (EMI), from the other components, and conversely, the other components are shielded from transmission from the wireless communication components.

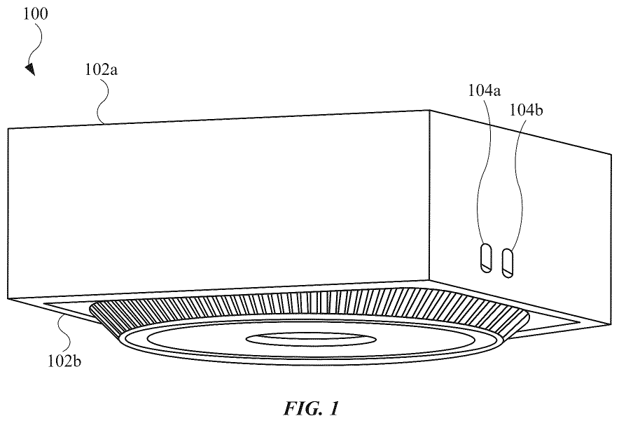

These and other embodiments are discussed below with reference to FIGS. 1-17. However, those skilled in the art will readily appreciate that the detailed description given herein with respect to these Figures is for explanatory purposes only and should not be construed as limiting.

FIG. 1 illustrates a perspective view of an embodiment of an electronic device 100, in accordance with aspects of the present disclosure. In some embodiments, electronic device 100 takes the form of a mobile wireless communication device, such as a smartphone or a tablet computing device. In other embodiments, electronic device 100 takes the form of a display. In the embodiment shown in FIG. 1, electronic device 100 takes the form of a desktop computing device, including a standalone computing device.

Electronic device 100 may include a housing component 102a and a housing component 102b. Housing components 102a and 102b may combine to form a housing, or enclosure, to enclose several components, which will be shown and described in further detail below. In one or more implementations, housing component 102a is formed from metal (e.g., aluminum, aluminum alloy) and housing component 102b is formed from non-metal (e.g., plastic). Housing component 102a may include an opening 104a and an opening 104b (representative of additional openings) that align with a respective port (e.g., input-output (I/O) port) designed to receive a cable and electrically connect electronic device 100 with other devices, such as other electronic devices, a power source, a memory device, and/or a display, as non-limiting examples.

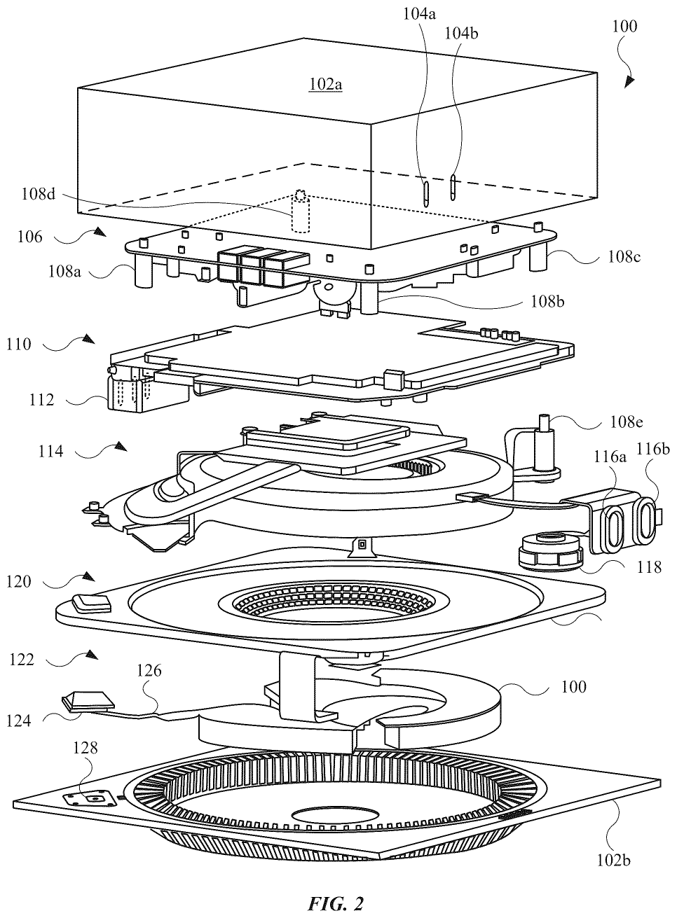

FIG. 2 illustrates an exploded view of electronic device 100 shown in FIG. 1, in accordance with aspects of the present disclosure. Several internal components of electronic device 100 positioned between housing components 102a and 102b are shown. In this regard, each of housing components 102a and 102b may define a respective internal volume for components of electronic device 100.

As shown, electronic device 100 may include a power system 106 designed to receive electrical power from an external power source and distribute electrical power to various components that use electrical power during operation, some of which will be described below. Power system 106 may include one or more components designed to receive alternating current (AC) from an external power source and convert AC to direct current (DC). Power system 106 may further include a battery (or batteries, or super capacitors) designed to store energy for use when power system 106 is not connected to the external power source or when power system 106 needs transient power in excess of the AC/DC capacity of the power system 106 alone.

In order to position power system 106 within housing component 102a in a desired manner, several pins may be used. For example, a pin 108a, a pin 108b, a pin 108c, and a pin 108d may pass through respective openings of power system 106, as shown in FIG. 2, and subsequently enter a cavity, or partial opening, within housing component 102a. This will be shown and described in further detail below. Additionally, each of pins 108a, 108b, 108c, and 108d may include a threaded region, or the cavity, designed to form a threaded engagement with a fastener or another threaded component.

Electronic device 100 may further include a computing system 110. Computing system 110 may include a circuit board (e.g., logic board or main logic board) and one or more processors (e.g., central processing unit, one or more microcontrollers, one or more application-specific integrated circuits) mechanically and electrically coupled to the circuit board. Further, computing system 110 may carry a port assembly 112 that includes one or more ports. Also, although not shown, computing system 110 may further carry additional fasteners (e.g., threaded fasteners), each of which is designed to form a threaded engagement with at least some of the pins (e.g., pin 108a) coupled with power system 106.

Electronic device 100 may further include a thermal system 114 designed to receive, redistribute, and expel heated air (e.g., thermal energy) from electronic device 100. Thermal system 114 may include several thermal components (e.g., thermal slug, heat pipe, fin stack, blower), each of which will be described in further detail below. Also, thermal system 114 may carry a pin 108e designed to pass through computing system 110 and couple (e.g., via threaded engagement) with pin 108c, thus coupling power system 106 with thermal system 114. As shown, computing system 110 may be positioned between power system 106 and thermal system 114.

Electronic device 100 may further include a port 116a, a port 116b (e.g., I/O ports), and an audio transducer 118. When positioned in housing component 102a, port 116a and port 116b may align opening 104a and opening 104b, respectively. Each of the ports 116a and 116b is designed to receive a cable or cable assembly (not shown in FIG. 2). Audio transducer 118 may take the form of an audio speaker, a microphone, or a combination thereof. Also, audio transducer 118 may electrically couple with computing system 110 by way of flexible circuitry. When positioned in housing component 102a, audio transducer 118 may communicate with the ambient environment via one or more openings (not shown in FIG. 2) of housing component 102b.

Electronic device 100 may further include a shield 120. Shield 120 may be formed from a metal. In this regard, shield 120 may take the form of a radiofrequency (RF) shield, such as a Faraday cage. Based on its position in housing component 102a, shield 120 may block RF energy from one or components generated from computing system 110 from reaching other components of electronic device 100. For example, electronic device 100 may further include a wireless communication system 122. As non-limiting examples, wireless communication system 122 may include wireless circuitry (e.g., integrated circuits, antennas) allowing electronic device 100 to communicate (e.g., transmit and receive) via protocol including WI-FI®, BLUETOOTH, and near-field communication (NFC), as non-limiting examples. Shield 120 may prohibit noise (e.g., electromagnetic interference or EMI) generated by one or more components of computing system 110. Additionally, shield 120 may prohibit exposure of wireless communication signals, received by or generated from wireless communication system 122, to the one or more components of computing system 110. Moreover, shield 120 may isolate a wireless communication circuit of wireless communication system 122 from one or more antennas of wireless communication system 122. Also, each of housing component 102b and shield 120 may include several openings (shown, not labeled). Based on the respective openings, ambient air may flow into electronic device 100 and heated air (e.g., exhaust) may flow out of electronic device 100. Further, shield 120 may provide protection against a thermal event (e.g., fire) within electronic device 100.

Wireless communication system 122 may electrically couple with a switch 124 via a flexible circuit 126. Further, housing component 102b may carry a button 128. In one or more implementations, button 128 takes the form of a power button. In this regard, button 128 may be actuated (e.g., by a user), which causes an actuation of switch 124. Actuation of switch 124 may power on or power off electronic device 100.

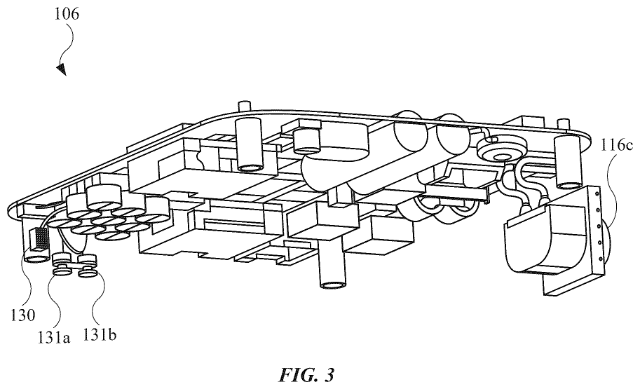

FIG. 3 illustrates a perspective view of power system 106 of electronic device 100, in accordance with aspects of the present disclosure. Power system 106 may include a port 116c. In one or more implementations, port 116c takes the form of an AC port. Accordingly, port 116c may receive AC power from an external power source, and power system 106 may convert AC to DC. Power system 106 may further include a connector 130 designed to electrically couple with computing system 110 (shown in FIG. 2) and facilitate communication (e.g., via electrical signals) between power system 106 and computing system 110. Power system 106 may further include a pin 131a and a pin 131b, each of which is designed to electrically couple with computing system 110 (shown in FIG. 2) and provide power (e.g., DC power) to computing system 110.

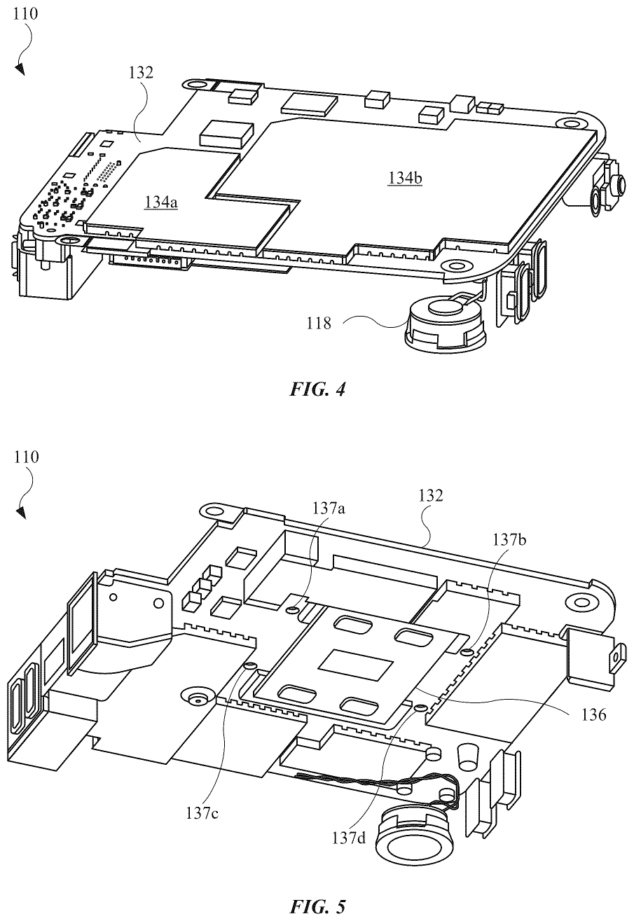

FIG. 4 and FIG. 5 illustrate perspective views of computing system 110 of electronic device 100 (shown in FIG. 2), in accordance with aspects of the present disclosure. Computing system 110 may include a circuit board 132 (e.g., main logic board) that carries several components. Referring to FIG. 4, a top perspective view of computing system 110 shows a can 134a and a can 134b positioned on circuit board 132. Each of cans 134a and 134b may include metal or metal alloy walls that combine to cover one or more electrical components (e.g., integrated circuits). In this regard, each of cans 134a and 134b may provide a noise shield for components between circuit board 132 and each of cans 134a and 134b, as well as prevent noise from the covered components (e.g., components covered by can 134a and can 134b) from emanating throughout electronic device 100 (shown in FIG. 1). Additionally, audio transducer 118 may be positioned in a housing (not shown in FIG. 4) that couples with computing system 110. The housing may provide a back volume for audio transducer 118.

Referring to FIG. 5, a bottom perspective view of computing system 110 shows an integrated circuit 136 coupled with circuit board 132. In one or more implementations, integrated circuit 136 takes the form of a system on chip (SOC). In this regard, integrated circuit 136 may combine several electronic circuits to perform various operations for electronic device 100 (shown in FIG. 1). As a result, integrated circuit 136 may generate significant heat during operation. Also, circuit board 132 may include several openings, such as an opening 137a, an opening 137b, an opening 137c, and an opening 137d. These will be discussed further below.

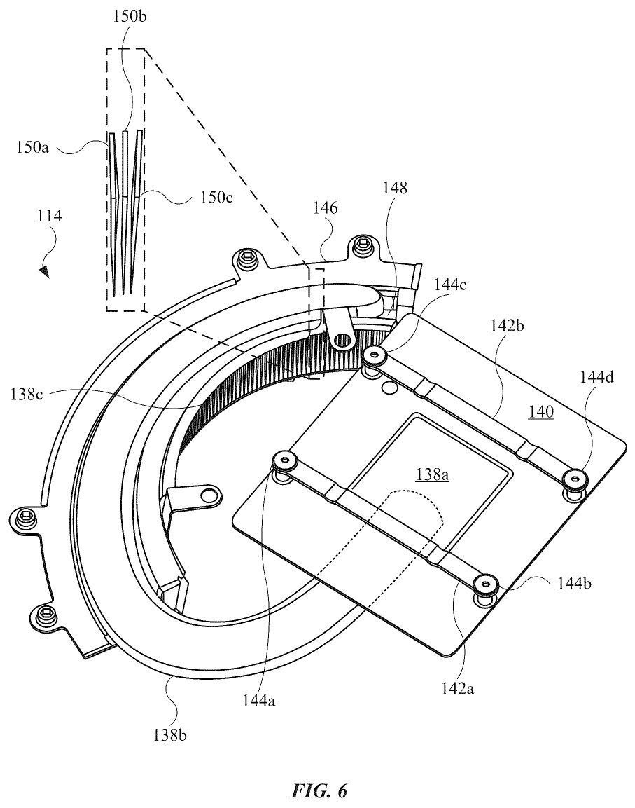

FIG. 6 and FIG. 7 illustrate perspective views of thermal system 114 of electronic device 100 (shown in FIG. 2), in accordance with aspects of the present disclosure. Thermal system 114 may include several thermal components. Referring to FIG. 6, thermal system 114 may include a thermal component 138a. In one or more implementations, thermal component 138a takes the form of a thermal slug. When electronic device 100 is assembled, thermal component 138a may be placed in direct contact with, or at last close proximity to, integrated circuit 136 (shown in FIG. 5). In this regard, thermal component 138a may thermally couple with integrated circuit 136, thus allowing heat generated by integrated circuit 136 to flow into thermal component 138a. As shown, thermal component 138a is carried by a platform 140.

In order to maintain thermal component 138a in thermal contact with integrated circuit 136, several springs may be used. For example, a spring 142a and a 142b may couple with circuit board 132 (shown in FIG. 5) by way of several fasteners (e.g., a fastener 144a, a fastener 144b, a fastener 144c, and a fastener 144d) that pass through respective openings of platform 140. Further, when coupled with circuit board 132 (shown in FIG. 5), circuit board 132 may be positioned between thermal component 138a and springs 142a and 142b. Each of springs 142a and 142b may include curved/bent state and may be subsequently flattened when the aforementioned fasteners secure the springs 142a and 142b with the circuit board 132. For example, fastener 144a and fastener 144b may pass through opening 137a and opening 137b (shown in FIG. 5), respectively, of circuit board 132. Fasteners 144a and 144b may apply a force to bend and flatten, or at least partially flatten, spring 142a. Similarly, fastener 144c and fastener 144d may pass through opening 137c and opening 137d (shown in FIG. 5), respectively, of circuit board 132, and apply a force to bend and flatten, or at least partially flatten, spring 142b. Springs 142a and 142b may apply a counterforce that causes the thermal component 138a to maintain direct contact with to integrated circuit 136 (shown in FIG. 5). Springs 142a and 142b may also apply uniform, or quasi-uniform, pressure through a thermal interface material.

Thermal system 114 may further include a thermal component 138b thermally coupled with thermal component 138a. In one or more implementations, thermal component 138b takes the form of a heat pipe designed to transport heat received from thermal component 138a. In this regard, thermal component 138b may transport heat via water vaper through its body. Thermal system 114 may further include a thermal component 138c thermally coupled with thermal component 138b. In one or more implementations, thermal component 138c takes the form of a fin stack designed to receive heat from thermal component 138b.

Also, thermal system 114 may include a mount 146 that carries thermal components 138b and 138c. Mount 146 is designed to couple with a blower (shown below). Mount 146 may include a curvature designed to match, or at least partially match, a curvature of the blower. Further, mount 146 may align thermal component 138c with a fan outlet of the blower. This will be shown below.

As shown, mount 146 includes a curved surface 148 that conforms to the curvature of thermal component 138b, thus allowing curved surface 148 to receive thermal component 138b. Also, thermal component 138c, when implemented as a fin stack, may include several fins oriented radially outward. In this regard, thermal component 138c may be characterized as a radial fin stack. As shown in the enlarged view, thermal component 138c may include a fin 150a, a fin 150b, and a fin 150c (each representative of additional fins). Due in part to fins 150a, 150b, and 150c extending radially outward, at least some (and in some cases, each) of fins 150a, 150b, and 150c may be non-parallel with respect to each other, as shown in FIG. 6. The non-parallel configuration of fins 150a, 150b, and 150c allows fins 150a, 150b, and 150c to follow the curvature of a blower. This will be shown below. Also, in one or more implementations, thermal component 138c is electrically coupled with shield 120 (shown in FIG. 2) and shield 120 provides an electrical grounding path for thermal component 138c.

Referring to FIG. 7, the thermal components of thermal system 114 include additional features. For example, thermal component 138b may include a bend 151a and a bend 151b. Bend 151a may cause one portion of thermal component 138b to be lower (e.g., along the Z-axis of Cartesian coordinates) than another portion, or conversely, one portion to be elevated relative to another portion. As a result, thermal component 138b, while being thermal coupled with thermal components 138a and 138b, may allow thermal component 138a to lie in a different plane (e.g., X-Y plane) than at least a portion of thermal component 138c. Beneficially, the thermal components 138a, 138b, and 138c may be thermally coupled together while also fitting into a relatively small enclosure (e.g., housing component 102a shown in FIG. 2) and also providing heat transfer capabilities. Also, based in part on bend 151b, thermal component 138b may transition in a different direction such that thermal component 138b is positioned on or over a surface of mount 146.

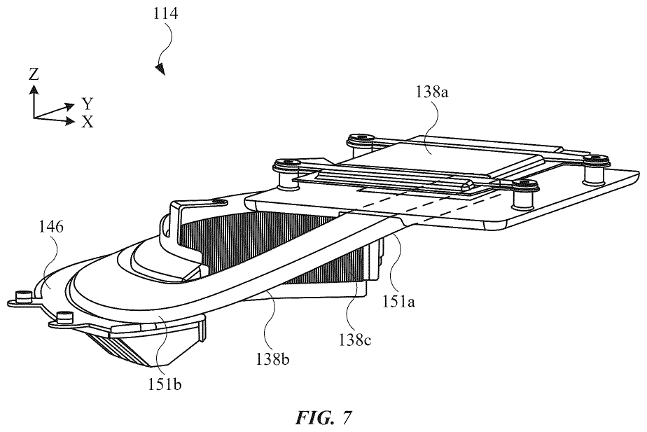

FIG. 8 and FIG. 9 illustrate perspective views of a blower 152 of electronic device 100 (shown in FIG. 2), in accordance with aspects of the present disclosure. Blower 152 may define an additional component of thermal system 114 (shown in FIG. 2). As non-limiting examples, blower 152 may take the form of fan or air mover. In this regard, blower 152 may include components such as an impeller and a motor that functions to drive (e.g., rotationally drive) the impeller.

Referring to FIG. 8, a top perspective view of blower 152 show blower 152 having a housing 154. Housing 154 may define a fan inlet 156a (e.g., opening) into which air (e.g., ambient air) is received through housing 154 during operation of blower 152. As shown, thermal component 138a is aligned (e.g., along an axis parallel to the Z-axis) with fan inlet 156a. The alignment between thermal component 138a and fan inlet 156a may provide additional cooling air to cool thermal component 138a. Housing 154 may further define a fan outlet 158 through which heated exhaust air exits blower 152. When mount 146 is coupled with blower 152 (e.g., with housing 154), each of thermal components 138b and 138c is aligned with fan outlet 158. As a result, heated air exiting blower 152 via fan outlet 158 may pass through thermal component 138c, including between fins of a fin stack of thermal component 138c. This may further cause heat received by thermal component 138c (at least some of which is provided by thermal component 138b) to exit thermal component 138c. Additionally, housing 154 may include chamfered portion 159, representing a curved (e.g., diagonal) surface of housing 154. Based on chamfered portion 159, housing 154 may occupy less volume within housing component 102a (shown in FIG. 2) while not interfering with operation of the impellers of blower 152. Beneficially, based on chamfered portion 159, other components, including thermal component 138b, may be located closer to blower 152.

Referring to FIG. 9, a bottom perspective view shows blower 152 having a base 160, or fan pillow, coupled with housing 154. Base 160 may include a fan inlet defined by several openings, such as an opening 161a, an opening 161b, and an opening 161c. In this regard, openings 161a, 161b, and 161c of fan inlet may receive air through base 160 during operation of blower 152. As shown, base 160 may include a base portion 163a and a base portion 163b that is diagonal with respect to base portion 163a. The configuration of radial fins of thermal component 138c allow thermal component 138c to conform to the curvature of base portion 163b. Additionally, mount 146 may also be curved and angle to conform to the shape of base 160, and in particular, to the shape of base portion 163b. Also, by forming base portion 163b at a diagonal, base 160 may accommodate other components, including I/O components. Referring to FIG. 8 and FIG. 9, based on the location of blower 152, as well as fan inlets of blower 152, blower 152 may drive ambient air through various components of electronic device 100 (shown in FIG. 2) such as power system 106 and computing system 110 (shown in FIG. 2).

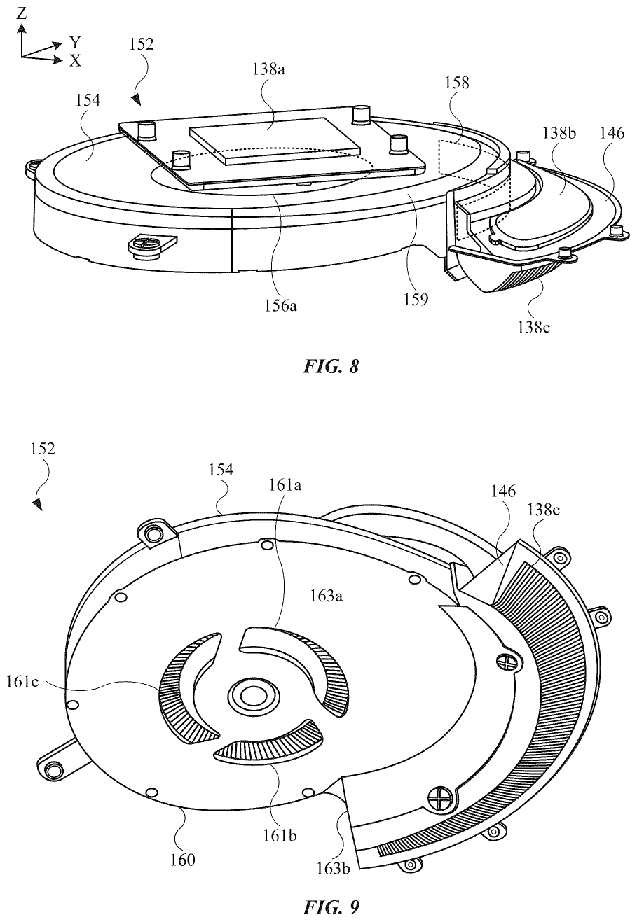

FIG. 10 illustrates a perspective view of computing system 110 and thermal components 138a, 138b, and 138c of electronic device 100 (shown in FIG. 2), in accordance with aspects of the present disclosure. In some implementations, computing system 110 and thermal components 138a, 138b, and 138c are installed together in housing component 102a (shown in FIG. 2). Prior to installing in housing component 102a, computing system 110 is rotated 180 degrees. In this regard, a bottom perspective view of computing system 110 is shown in FIG. 10. Several ports (e.g., I/O ports) of port assembly 112 are shown. For example, port assembly 112 may include a port 116d, a port 116e, and a port 116f. In one or more implementations, each of ports 116d, 116e, and 116f take the form of a Universal Serial Bus (USB) port, which may include a USB-C port. Additionally, port assembly 112 may include a port 116g and a port 116h. In one or more implementations, port 116g and port 116h take the form of a High-Definition Multimedia Interface (HDMI) port and an Ethernet (e.g., RJ45) port, respectively.

Port assembly 112 may include several protrusions (e.g., pins, extensions). For example, port assembly 112 may include a protrusion 162a, a protrusion 162b, a protrusion 162c, and protrusion 162d. At least some of protrusions 162a, 162b, 162c, and 162d are representative of additional protrusions (shown, not labeled).

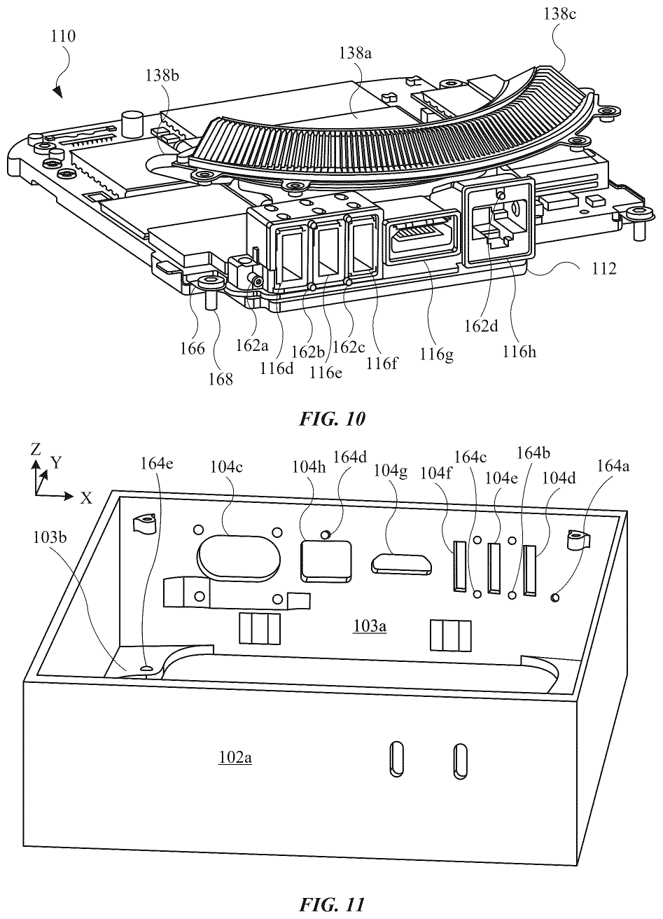

FIG. 11 illustrates an internal perspective view of housing component 102a of electronic device 100 (shown in FIG. 2), in accordance with aspects of the present disclosure. As shown, housing component 102a may include several openings. For example, housing component 102a may include an opening 104c that aligns with port 116c (shown in FIG. 3).

Additionally, housing component 102a includes an opening 104d, an opening 104e, an opening 104f, an opening 104g, and an opening 104h. When computing system 110 (shown in FIG. 10) is inserted into housing component 102a, ports 116d, 116e, 116f, 116g, and 116h (shown in FIG. 10) may align with openings 104d, 104e, 104f, 104g, and 104h, respectively. In order to align the aforementioned ports with the aforementioned openings, housing component 102a may include several cavities. For example, housing component 102a may include a cavity 164a, a cavity 164b, a cavity 164c, and a cavity 164d designed to receive protrusion 162a, protrusion 162b, and protrusion 162c, respectively (shown in FIG. 10). Cavities 164a, 164b, 164c, and 164d may define indentation in housing component 102a.

As shown, cavities 164a, 164b, 164c, and 164d, are located on a wall 103a of housing component 102a. Housing component 102a may further include a wall 103b that is perpendicular with respect to wall 103a. Further, wall 103b may include a cavity 164d. When power system 106 (shown in FIG. 2) is positioned in housing component 102a, a pin (e.g., pin 108a) may be positioned in cavity 164e.

Referring to FIG. 10 and FIG. 11, when protrusion 162a is position in cavity 164a, the position of computing system 110 is generally set within housing component 102a. This may include setting computing system 110 in along both the X-and Z-axes (shown in FIG. 11). When protrusion 162b and protrusion 162c are positioned in cavity 164b and cavity 164c, respectively, one or more components (e.g., electrical ground springs) within ports 116a, 116b, and 116c are protected from undesired contact with housing component 102a. Further, when protrusion 162d is positioned in cavity 164d, computing system 110 is prevented from rotating or rocking within housing component 102a. Additionally, referring to FIG. 10, a tab 166 (e.g., spring tab) extending from computing system 110 may include an opening that receives a fastener 168 that couples with (e.g., connects to) pin 108d (shown in FIG. 2). This connection between fastener 168 and the pin 108d may fix computing system 110 vertically (e.g., along the Z-axis) within housing component 102a, while tab 166 provides some flexibility to offset tolerance variations.

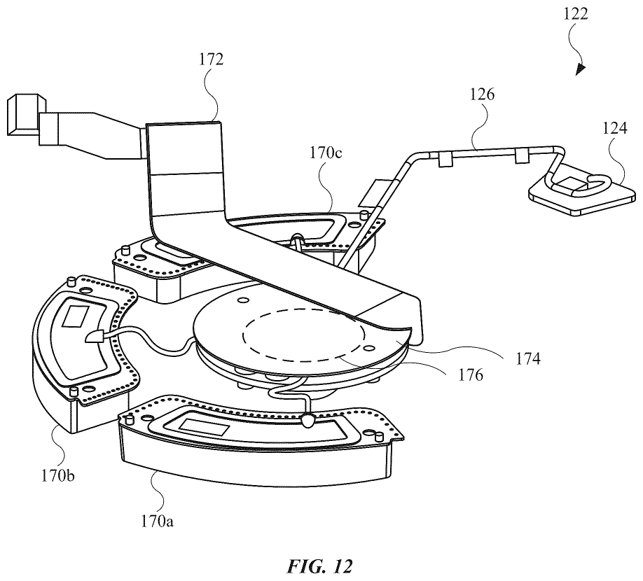

FIG. 12 illustrates a perspective view of wireless communication system 122 of electronic device 100 (shown in FIG. 2), in accordance with aspects of the present disclosure. While several components are positioned in housing component 102a (shown in FIG. 2), wireless communication system 122 may be positioned, or at least partially positioned, in housing component 102b (shown in FIG. 2). As shown, wireless communication system 122 may include several antennas, such as an antenna 170a, an antenna 170b, and an antenna 170c. Each of antennas 170a, 170b, and 170c may permit wireless RF communication in accordance with a respective wireless protocol (e.g., WI-FI®, BLUETOOTH®, or the like).

In addition to flexible circuit 126 electrically coupled with switch 124, wireless communication system 122 may further include a flexible circuit 172 designed to electrically couple with computing system 110 (shown in FIG. 2). In this regard, signals (e.g., electrical signals) from wireless communication system 122 and switch 124 may be provided to computing system 110 via flexible circuit 172. Wireless communication system 122 may further include a wireless communication circuit 174 designed to process RF communication received by and/or transmitted via antennas 170a, 170b, and 170c. Wireless communication system 122 may further include a battery 176 covered by wireless communication circuit 174. Battery 176 may provide a backup power source, and may be readily discarded based on its location. Also, wireless communication system 122 may be positioned relative to shield 120 (shown in FIG. 2) such that shield 120 isolates wireless communication circuit 174 and battery 176 from antennas 170a, 170b, and 170c. Wireless communication circuit 174 and battery 176 may be positioned within shield 120 and antennas 170a, 170b, and 170c may be positioned outside of shield 120. In this regard, wireless communication circuit 174 and battery 176 are not exposed to RF communication received by or transmitted from antennas 170a, 170b, and 170c. Battery 176 may be positioned in an opening (e.g., centrally-located opening of shield 120. As a result, battery 176 may be easily removed and subsequently replaced and mended with conductive gaskets and a separate metallic cover positioned over a replacement battery.

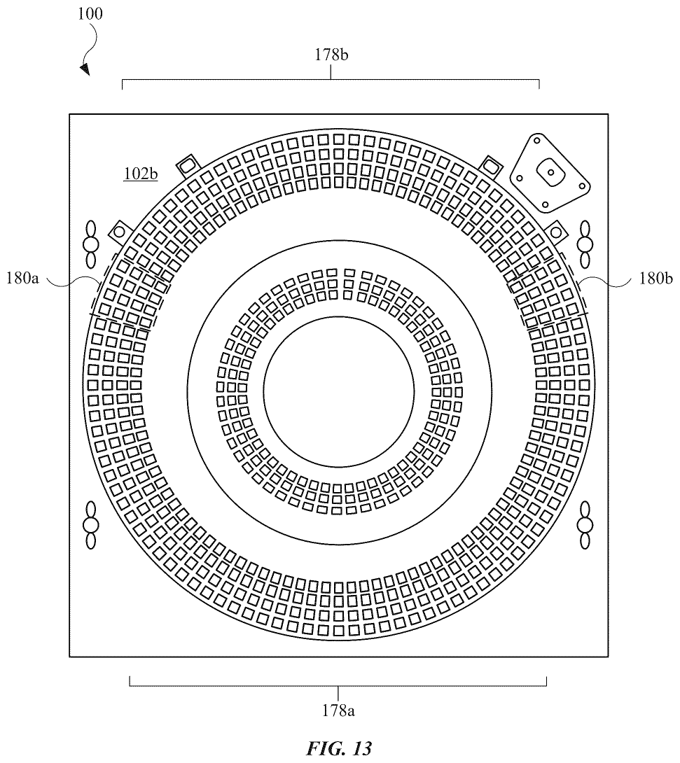

FIG. 13 illustrates a bottom view of electronic device 100, showing features of housing component 102b, in accordance with aspects of the present disclosure. As shown, housing component 102b includes several openings, such as openings 178a (e.g., set of openings) and openings 178b (e.g., set of openings). Additionally, an air blocking structure 180a and an air blocking structure 180b cover at least some openings of housing component 102b. As a result, air blocking structures 180a and 180b separate openings 178a from openings 178b. As non-limiting examples, each of air blocking structures 180a and 180b may take the form of an adhesive or a polymer-based barrier.

During operation of blower 152 (shown in FIG. 6), air (e.g. ambient air outside of electronic device 100) may enter electronic device 100 via openings 178a of housing component 102b. In this regard, openings 178a may represent a location of air entry into electronic device 100 to cool the aforementioned components of electronic device 100. Additionally, blower 152, during operation, may drive air out of electronic device 100 via openings 178b of housing component 102b. In this regard, openings 178b may represent a location of air exit out electronic device 100 after the air is heated. Using air blocking structures 180a and 180b, the exiting exhaust may not mix with the ambient, cool air. Beneficially, heated air may not reenter the electronic device 100.

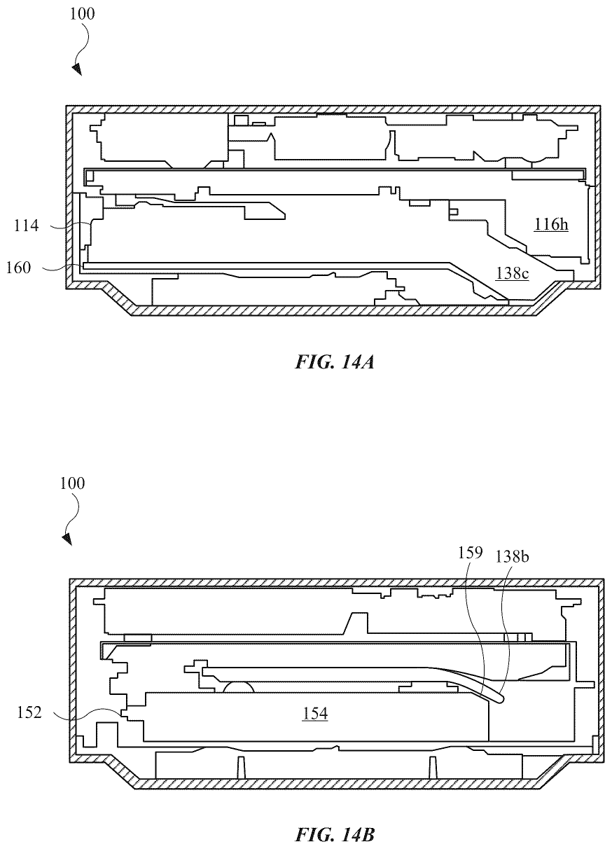

FIG. 14A and FIG. 14B illustrate partial cross sectional views of an electronic device 100, in accordance with aspects of the present disclosure. The partial cross sectional views are taken through different locations of electronic device 100. Referring to FIG. 14A, based in part on base 160, thermal component 138c may be positioned, or angled, to accommodate port 116h (shown in FIG. 10). Also, port 116h may be chamfered in order to provide clearance from thermal component 138c, including the angular position of thermal component 138c. Referring to FIG. 14B, chamfered portion 159 of housing 154 (of blower 152) allows thermal component 138b to be positioned in a location that would otherwise be occupied, or at least partially occupied, by housing 154.

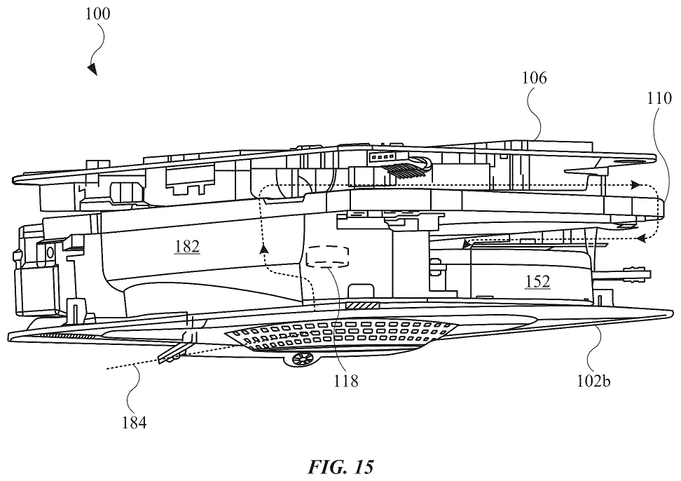

FIG. 15 illustrates a perspective view of several components of electronic device 100 (e.g., shown in FIG. 1), further showing an exemplary airflow path through the components, in accordance with aspects of the present disclosure. As shown, a housing 182 is integrated with computing system 110. Housing 182 may provide an enclosure for components such as audio transducer 118. In this regard, housing 182 may be referred to as a speaker housing. Based on its dimensions (e.g., size and shape), housing 182 may also provide a back volume for audio transducer 118.

Also, FIG. 15 shows an exemplary airflow path through the various components. For example, a dotted line 184 represents a path of airflow entering housing component 102b via openings (e.g., openings 178a shown in FIG. 15). Based on the locating of housing 182, the airflow may subsequently passes around housing 182. In this regard, housing 182 may baffle the airflow within housing component 102a (shown in FIG. 1). The airflow may subsequently pass around housing 182 and through a space, or spaces, between power system 106 and computing system 110, including spaces between the respective components of power system 106 and computing system 110. Beneficially, the airflow, representing cool ambient air, may cool components of both power system 106 and computing system 110. The airflow may subsequently pass along an opposing surface of computing system 110 and into blower 152. The arrangement and position of blower 152 causes reduced pressure at one of the blower inlets (e.g., fan inlet 156a of blower 152 in FIG. 9), thus forcing air into electronic device 100 and through and/or around the aforementioned components of electronic device 100.

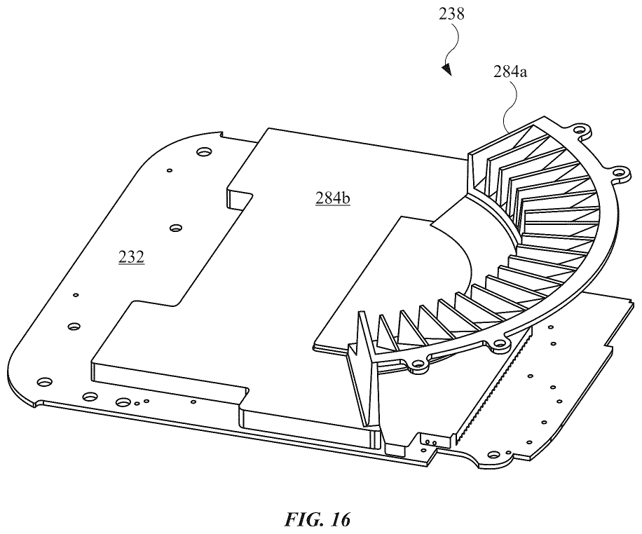

FIG. 16 illustrates a perspective view of an alternate embodiment of a thermal component 238, in accordance with aspects of the present disclosure. As shown, thermal component 238 may include several thermal members. For example, thermal component 238 may include a thermal member 284a and a thermal member 284b. As shown, thermal component 238 may be mounted to a circuit board 232. In one or more implementations, thermal member 284a takes the form of a fin stack through which airflow passes. Similar to the thermal component 138c (shown in FIG. 6), thermal member 284a may include radial fins. Also, in one or more implementations, thermal member 284b takes the form of a base plate that functions as a heat spreader. Additionally, thermal member 284b may function as a shield (e.g., EMI shield) to prohibit noise generated by one or more components (e.g., integrated circuits) mounted on circuit board 232. Each of thermal members 284a and 284b may be formed from a metal (e.g., aluminum, aluminum alloy). Also, thermal members 284a and 284b may be formed through a casting operation such that thermal members 284a and 284b, as a non-limiting example. In this regard, thermal members 284a and 284b may be integrated together.

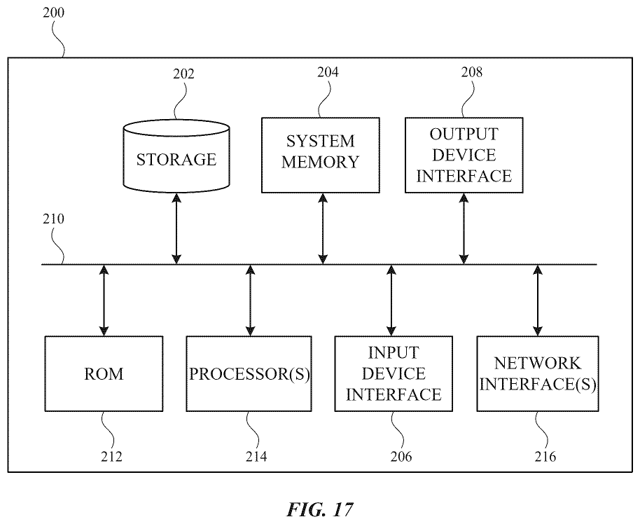

FIG. 17 illustrates an electronic system 200 with which one or more implementations of the subject technology may be implemented. The electronic system 200 can be, and/or can be a part of, the electronic device 100 shown in FIG. 1. The electronic system 200 may include various types of computer readable media and interfaces for various other types of computer readable media. The electronic system 200 includes a bus 210, one or more processing units 214, a system memory 204 (and/or buffer), a ROM 212, a permanent storage device 202, an input device interface 206, an output device interface 208, and one or more network interfaces 216, or subsets and variations thereof.

The bus 210 collectively represents all system, peripheral, and chipset buses that communicatively connect the numerous internal devices of the electronic system 200. In one or more implementations, the bus 210 communicatively connects the one or more processing units 214 with the ROM 212, the system memory 204, and the permanent storage device 202. From these various memory units, the one or more processing units 214 retrieves instructions to execute and data to process in order to execute the processes of the subject disclosure. The one or more processing units 214 can be a single processor or a multi-core processor in different implementations.

The ROM 212 stores static data and instructions that are needed by the one or more processing units 214 and other modules of the electronic system 200. The permanent storage device 202, on the other hand, may be a read-and-write memory device. The permanent storage device 202 may be a non-volatile memory unit that stores instructions and data even when the electronic system 200 is off. In one or more implementations, a mass-storage device (such as a magnetic or optical disk and its corresponding disk drive) may be used as the permanent storage device 202.

In one or more implementations, a removable storage device (such as a flash drive, and its corresponding disk drive) may be used as the permanent storage device 202. Like the permanent storage device 202, the system memory 204 may be a read-and-write memory device. However, unlike the permanent storage device 202, the system memory 204 may be a volatile read-and-write memory, such as random access memory. The system memory 204 may store any of the instructions and data that one or more processing units 214 may need at runtime. In one or more implementations, the processes of the subject disclosure are stored in the system memory 204, the permanent storage device 202, and/or the ROM 212 (which are each implemented as a non-transitory computer-readable medium). From these various memory units, the one or more processing units 214 retrieves instructions to execute and data to process in order to execute the processes of one or more implementations.

The bus 210 also connects to the input device interface 206 and output device interface 208. The input device interface 206 enables a user to communicate information and select commands to the electronic system 200. Input devices that may be used with the input device interface 206 may include, for example, alphanumeric keyboards and pointing devices (also called “cursor control devices”). The input device interface 206 may enable, for example, the display of images generated by electronic system 200. Output devices that may be used with the input device interface 206 may include, for example, printers and display devices, such as a liquid crystal display (LCD), a light emitting diode (LED) display, an organic light emitting diode (OLED) display, a flexible display, a flat panel display, a solid state display, a projector, or any other device for outputting information. One or more implementations may include devices that function as both input and output devices, such as a touchscreen. In these implementations, feedback provided to the user can be any form of sensory feedback, such as visual feedback, auditory feedback, or tactile feedback; and input from the user can be received in any form, including acoustic, speech, or tactile input.

The bus 210 may also couple the electronic system 200 to one or more networks and/or to one or more network nodes through the one or more network interfaces 216. In this manner, the electronic system 200 can be a part of a network of computers (such as a LAN, a wide area network (“WAN”), or an Intranet, or a network of networks, such as the Internet. Any or all components of the electronic system 200 can be used in conjunction with the subject disclosure.

These functions described above can be implemented in computer software, firmware or hardware. The techniques can be implemented using one or more computer program products. Programmable processors and computers can be included in or packaged as mobile devices. The processes and logic flows can be performed by one or more programmable processors and by one or more programmable logic circuitry. General and special purpose computing devices and storage devices can be interconnected through communication networks.

Various examples of aspects of the disclosure are described below as clauses for convenience. These are provided as examples, and do not limit the subject technology.

Clause A: An electronic device may include a blower comprising a fan inlet and a fan outlet. The electronic device may further include a first thermal component aligned with the fan inlet. The electronic device may further include a second thermal component thermally coupled with the first thermal component. The second thermal component may include a first bend and a second bend. The second thermal component is aligned with the fan outlet based on the first bend and the second bend.

Clause B: An electronic device may include a first housing component that includes a first cavity. The first housing component may define an internal volume configured to receive components. The components may include a power system comprising an opening. The components may further include a pin positioned in the opening. The components may further include a computing system comprising a tab. The components may further include a first protrusion carried by the computing system. The first protrusion may be positioned in the first cavity. The components may further include a fastener passing through the opening and coupled with the pin.

Clause C: An electronic device may include a blower. The blower may include a housing that defines a fan inlet and a fan outlet. The housing may include a chamfered portion. The blower may further include a base coupled with the housing. The base may include a first portion. The base may include a second portion diagonal with respect to the first portion. The electronic device may further include a first thermal component aligned with the fan inlet. The electronic device may further include a second thermal component thermally coupled with the first thermal component, the second thermal component comprising a first bend and a second bend, wherein the second thermal component is aligned with the fan outlet and the chamfered portion based on the first bend and the second bend. The electronic device may further include a mount coupled with the second thermal component, wherein the mount is coupled with the base at the second portion.

Clause D: An electronic device may include a plurality of thermal components. The thermal components may include a thermal slug. The thermal components may further include a heat pipe thermally coupled with the thermal slug. The thermal components may further include a fin stack thermally coupled with the heat pipe. The electronic device may further include a computing system stacked over the plurality of thermal components. The electronic device may further include a power system stacked over the computing system.

One or more of the above clauses can include one or more of the features described below. It is noted that any of the following clauses may be combined in any combination with each other, and placed into a respective independent clause, e.g., clause A, B, C or D.

Clause 1: further including a mount coupled with the blower, wherein the second thermal component is carried by the mount.

Clause 2: further including a third thermal component carried by the mount, wherein the third thermal component is aligned with the fan outlet.

Clause 3: wherein: the first thermal component includes a thermal slug, the second thermal component includes a heat pipe, and the third thermal component includes a fin stack.

Clause 4: wherein: the mount includes a curved surface, and the second thermal component is positioned over the curved surface.

Clause 5: further including: a power system; and a circuit board positioned between the power system and the blower.

Clause 6: further including: a wireless communication system; and a shield positioned between the wireless communication system and the blower.

Clause 7: further including: a flexible circuit electrically coupled with the circuit board; and a switch configured to be actuated by a button, the switch electrically coupled with the flexible circuit, wherein the wireless communication system includes a wireless communication circuit electrically coupled with the flexible circuit.

Clause 8: wherein the components further include: a blower including a fan inlet and a fan outlet; a first thermal component aligned with the fan inlet; and a second thermal component thermally coupled with the first thermal component, the second thermal component including a first bend and a second bend. The second thermal component is aligned with the fan outlet based on the first bend and the second bend.

Clause 9: wherein the components further including: a mount coupled with the blower, wherein the second thermal component is carried by the mount; and a third thermal component carried by the mount, wherein the third thermal component is aligned with the fan outlet.

Clause 10: wherein: the first thermal component includes a thermal slug, the second thermal component includes a heat pipe, and the third thermal component includes a fin stack.

Clause 11: wherein: the fin stack includes a first fin and a second fin, and the first fin and the second fin extend radially outward from the fan outlet such that the first fin is non-parallel with respect to the second fin.

Clause 12: wherein the blower includes a base, the base including: a first portion; and a second portion diagonal with respect to the first portion, wherein the mount is coupled with the base at the second portion.

Clause 13: further including a second housing component coupled with the first housing component, wherein the second housing component includes: a first set of openings configured to receive air during operation of the blower; and a second set of openings configured to expel some of the air during operation of the blower, the first set of openings separate from the first set of openings.

Clause 14: wherein: the first housing component further includes a second cavity, and the components further include: a port coupled with the computing system, the port configured to receive a cable; and a second protrusion carried by the computing system, wherein the second cavity is configured to receive the second protrusion to align the computing system in the first housing component.

Clause 15: wherein: the first cavity is formed in a first wall of the first housing component, and the second cavity is formed in a second wall of the first housing component, the second wall perpendicular with respect to the first wall.

Clause 16: further including a third thermal component coupled with the mount.

Clause 17: wherein: the first thermal component includes a thermal slug, the second thermal component includes a heat pipe, and the third thermal component includes a fin stack.

Clause 18: further including: an audio transducer and a housing that provides a back volume for the audio transducer, the housing integrated with the power system.

Clause 19: further including a blower configured to drive air, wherein the housing is configured to direct at least some of the air.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

The predicate words “configured to”, “operable to”, and “programmed to” do not imply any particular tangible or intangible modification of a subject, but, rather, are intended to be used interchangeably. In one or more implementations, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

The word “exemplary” is used herein to mean “serving as an example, instance, or illustration”. Any embodiment described herein as “exemplary” or as an “example” is not necessarily to be construed as preferred or advantageous over other embodiments. Furthermore, to the extent that the term “include”, “have”, or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for”.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more”. Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

1. An electronic device, comprising:
a blower comprising a fan inlet and a fan outlet;
a first thermal component aligned with the fan inlet; and
a second thermal component thermally coupled with the first thermal component, the second thermal component comprising a first bend and a second bend, wherein the second thermal component is aligned with the fan outlet based on the first bend and the second bend.

2. The electronic device of claim 1, further comprising a mount coupled with the blower, wherein the second thermal component is carried by the mount.

3. The electronic device of claim 2, further comprising a third thermal component carried by the mount, wherein the third thermal component is aligned with the fan outlet.

4. The electronic device of claim 3, wherein:
the first thermal component comprises a thermal slug,
the second thermal component comprises a heat pipe, and
the third thermal component comprises a fin stack.

5. The electronic device of claim 2, wherein:
the mount comprises a curved surface, and
the second thermal component is positioned over the curved surface.

6. The electronic device of claim 1, further comprising:
a power system; and
a circuit board positioned between the power system and the blower.

7. The electronic device of claim 6, further comprising:
a wireless communication system; and
a shield positioned between the wireless communication system and the blower.

8. The electronic device of claim 7, further comprising:
a flexible circuit electrically coupled with the circuit board; and
a switch configured to be actuated by a button, the switch electrically coupled with the flexible circuit, wherein the wireless communication system comprises a wireless communication circuit electrically coupled with the flexible circuit.

9. An electronic device, comprising:
a first housing component comprising a first cavity, the first housing component defining an internal volume configured to receive components, the components comprising:
a power system comprising an opening;
a pin positioned in the opening;
a computing system comprising a tab;
a first protrusion carried by the computing system, the first protrusion positioned in the first cavity; and
a fastener passing through the opening and coupled with the pin.

10. The electronic device of claim 9, wherein the components further comprise:
a blower comprising a fan inlet and a fan outlet;
a first thermal component aligned with the fan inlet; and
a second thermal component thermally coupled with the first thermal component, the second thermal component comprising a first bend and a second bend, wherein the second thermal component is aligned with the fan outlet based on the first bend and the second bend.

11. The electronic device of claim 10, wherein the components further comprising:
a mount coupled with the blower, wherein the second thermal component is carried by the mount; and
a third thermal component carried by the mount, wherein the third thermal component is aligned with the fan outlet.

12. The electronic device of claim 11, wherein:
the first thermal component comprises a thermal slug,
the second thermal component comprises a heat pipe, and
the third thermal component comprises a fin stack.

13. The electronic device of claim 12, wherein:
the fin stack comprises a first fin and a second fin, and
the first fin and the second fin extend radially outward from the fan outlet such that the first fin is non-parallel with respect to the second fin.

14. The electronic device of claim 11, wherein the blower comprises a base, the base comprising:
a first portion; and
a second portion diagonal with respect to the first portion, wherein the mount is coupled with the base at the second portion.

15. The electronic device of claim 14, further comprising a second housing component coupled with the first housing component, wherein the second housing component comprises:
a first set of openings configured to receive air during operation of the blower; and
a second set of openings configured to expel some of the air during operation of the blower, the first set of openings separate from the first set of openings.

16. The electronic device of claim 9, wherein:
the first housing component further comprises a second cavity, and
the components further comprise:
a port coupled with the computing system, the port configured to receive a cable; and
a second protrusion carried by the computing system, wherein the second cavity is configured to receive the second protrusion to align the computing system in the first housing component.

17. The electronic device of claim 16, wherein:
the first cavity is formed in a first wall of the first housing component, and
the second cavity is formed in a second wall of the first housing component, the second wall perpendicular with respect to the first wall.

18. An electronic device, comprising:
a blower comprising:
a housing that defines a fan inlet and a fan outlet, the housing comprising a chamfered portion, and
a base coupled with the housing, the base comprising a first portion and a second portion diagonal with respect to the first portion;
a first thermal component aligned with the fan inlet; and
a second thermal component thermally coupled with the first thermal component, the second thermal component comprising a first bend and a second bend, wherein the second thermal component is aligned with the fan outlet and the chamfered portion based on the first bend and the second bend; and
a mount coupled with the second thermal component, wherein the mount is coupled with the base at the second portion.

19. The electronic device of claim 18, further comprising a third thermal component coupled with the mount.

20. The electronic device of claim 19, wherein:
the first thermal component comprises a thermal slug,
the second thermal component comprises a heat pipe, and
the third thermal component comprises a fin stack.

21.-23. (canceled)
